(19) United States
(12) Patent Application Publication
(10) Pub. No.: US 2014/0261635 A1
(43) Pub. Date: Sep. 18, 2014

(54) ELECTRICAL TERMINATIONS FOR FLEXIBLE PHOTOVOLTAIC MODULES

(71) Applicants: Eric Ng, Mountain View, CA (US); Nazir Ahmad, San Jose, CA (US)

(72) Inventors: Eric Ng, Mountain View, CA (US); Nazir Ahmad, San Jose, CA (US)

(73) Assignee: Nanosolar, Inc., San Jose, CA (US)

(21) Appl. No.: 13/799,186

(22) Filed: Mar. 13, 2013

(51) Int. Cl. H01L 31/048

(52) U.S. Cl. CPC H01L 31/0487; H01L 31/0485
USPC 136/251; 136/244; 136/256

(57) ABSTRACT

In a photovoltaic module, the solar cells and other necessary layers may be placed on a backsheet. The backsheet is configured to provide physical protection of the underside of the module and also provide physical protection to electrical terminals by wrapping itself around the connections. It is emphasized that this abstract is provided to comply with the rules requiring an abstract that will allow a searcher or other reader to quickly ascertain the subject matter of the technical disclosure. It is submitted with the understanding that it will not be used to interpret or limit the scope or meaning of the claims.

### FIELD OF THE DISCLOSURE

This invention relates generally to solar power systems. More particularly, it relates to apparatus and methods of photovoltaic or solar module design and fabrication.

### BACKGROUND OF THE INVENTION

Solar cells convert sunlight into electricity. Traditional solar cell modules have a plurality of polycrystalline and/or monocrystalline silicon solar cells mounted on a support with a rigid glass top layer to provide environmental and structural protection to the underlying cells. The package is in turn mounted on a rigid metal frame that supports the glass and provides attachment points for securing the module to the installation site. Other materials, such as junction boxes, bypass diodes, sealants, and/or multi-contact connectors, are provided to allow for electrical connection to other solar modules and/or electrical devices. Drawbacks associated with traditional solar module package designs have limited the ability to install large numbers of solar panels in a cost-effective manner. Specifically, traditional solar module packaging comes with a great deal of redundancy and excess equipment cost, such as aluminum frames, untold meters of cablings, and other components.

Over the years, thin film photovoltaic has become a new trend of solar technology. A thin film solar cell, also called a thin film PV cell, is a solar cell that is made by depositing one or more thin layers of photovoltaic material on a substrate. Photovoltaic materials include amorphous silicon, and other thin film silicon, cadmium telluride (CdTe), copper indium gallium selenide (CIS or CIGS), and dye-sensitized solar cell and other organic solar cells. Additionally, PV cells may be fabricated on low cost substrates or on flexible, light-weight substrates. In particular, the substrate or backsheet is the outermost layer of the PV module to protect the inner components of the module, specifically the PV cells and electrical components. It may provide physical protection from damage, moisture, water ingress and UV degradation, and also provide electrical insulation and long-term unit stability. As such, thin film PV technology provides substantial improvement for PV modules on manufacturing cost reduction and the ease of installation.

Similar to traditional solar cell modules, a thin film PV module has a plurality of PV cells electrically connected together to produce direct current (DC) power. An inverter is provided to convert the collected power to a certain desired voltage or alternating current (AC). Additionally, the positive and negative outputs of each PV module are connected to a respective electrical wire or cable through a junction box. In particular, the junction box serves as a shield for the connection made between a ribbon for the positive connection and an electrical cable and connection between another ribbon for the negative connection to another cable. The junction box is a cost adder and may also cause inherent failure points due to wet leakage from the interfaces which may break down over time.

### BRIEF DESCRIPTION OF THE DRAWINGS

FIG. 1 is a cross-sectional view of a solar module in accordance with the present disclosure;

FIG. 2 shows a cross-section view of a portion of an array of solar cells in accordance with the present disclosure;

FIG. 3 shows a close-up view of an electrical connection on a module in accordance with the present disclosure;

FIG. 4 shows a close-up view of an electrical connection on a module in accordance with the present disclosure;

FIG. 5 shows a close-up view of an electrical connections on a module in accordance with the present disclosure; and

FIG. 6 shows modules coupled together in accordance with the present disclosure.

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, the aspects of the present disclosure described below are set forth without any loss of generality to, and without imposing limitations upon, the claims that follow this description.

In this specification and the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for an anti-reflective film, this means that the anti-reflective film feature may or may not be present, and thus, the description includes both structures wherein a device possesses the anti-reflective film feature and structures wherein the anti-reflective film feature is not present.

FIG. 1 shows a non-to-scale cross-sectional view of a solar module 100 in accordance with the present disclosure. The solar module 100 may include a top layer 110, a top encapsulant layer 120, an array of solar cells 130, a bottom encapsulant layer 140, a backsheet 150 and at least one conductive tab 160.

The top layer 110 is a transparent layer. By way of non-limiting example, the top layer 110 may be made of a plastic barrier film such as a 3M™ UBF-9L and 510. In another example, the top layer 110 may be a glass layer comprised of materials such as conventional glass, solar glass, high-light transmission glass with low iron content, standard light transmission glass with standard iron content, anti-glare finish glass, glass with a stippled surface, fully tempered glass, heat-strengthened glass, annealed glass, or combinations thereof. The thickness of the top layer 110 may be in the range from about 100 to about 400 microns (μm).

The top encapsulant layer 120 may include any of a variety of pottant materials, such as but not limited to poly(ethylene-co-tetrafluoroethylene) (also known as ETFE and sometimes sold under the name Tefzel®), polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous PET, urethane acrylic, acrylic, other fluoroelastomers, other materials of similar qualities, or combinations thereof. The thickness of the top encapsulant layer 120 may be in the range of about 400 μm or thinner. Optionally, some embodiments may have more than two encapsulant layers and some may have only one encapsulant layer (either layer 120 or 140).

The layer 130 is an array of solar cells. FIG. 2 illustrates a portion of an array 130 of solar cells that are series connected. The array 130 includes a first cell 130a and a second cell 130b. Each cell may include a device layer 131a (131b), a bottom electrode 132a (132b), an insulating layer 133a (133b), and a backside top electrode 134a (134b).

The device layer 131a (131b) may include a transparent conductive layer and an active layer sandwiched between the transparent layer and the bottom electrode 132a (132b). The transparent conductive layer may be a transparent conductive oxide (TCO) such as zinc oxide (ZnO) or aluminum doped oxide (ZnO:Al), which may be deposited by sputtering, evaporation, CBD, electroplating, CVD, PVD, ALD, and the like. Alternatively, the transparent conductive layer may include a transparent conductive polymer layer, e.g., a transparent layer of doped PEDOT (Poly-3,4-Ethylenedioxythiophene), which may be deposited by spinning, dipping or spray coating. The active layer may include an absorber layer. In one example, the absorber layer may be made of copper-indium-gallium-selenium (for CIGS solar cells). It should be understood that the module 100 is not limited to any particular type of solar cell. By way of non-limiting example, the active layer may alternatively have absorber layers comprised of silicon (monocrystalline or polycrystalline), amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), CdSe, CdTe, Cu(In,Ga)(S,Se)₂, Cu(In,Ga,Al)(S,Se,Te)₂, and/or combinations of the above, where the active materials are present in any of several forms including but not limited to bulk materials, micro-particles, nano particles, or quantum dots.

The bottom electrode 132a (132b) may be made of a conductive material, such as aluminum foil, about 50 to about 200 μm thick. The insulating layer 133a (133b) may be made of plastic material, such as polyethylene teraphthalate (PET) about 20 to about 80 μm thick. The backside top electrode 134a (134b) may be made of a conductive material, such as aluminum foil about 50 to about 200 μm thick. The cell 130a (130b) may have a finger pattern over the transparent conductive layer. The finger pattern 135a (135b) may be made of a conductive material and electrically connected to the transparent conductive layer. An electrical contact is formed between the finger 135a (135b) to the backside top electrode 134a (134b). As shown in FIG. 2, for the electrical connection, vias 136a (136b) may be formed through the device layer 131a (131b), the bottom electrode 132a (132b), and the insulating layer 133a (133b). The vias 136a, 136b may be about 200 to about 1000 μm in diameter. The vias 136a (136b) may be formed, e.g., by punching or by drilling or by some combination of thereof. An insulating material may be coated along sidewalls of the via to avoid electrical contact with the device layer 131a, the bottom electrode 132a (132b), and the insulating layer 133a (133b). The cell 130a may be in series connection with the cell 130b by, for example, coupling the backside top electrode 134a of the cell 130a to the bottom electrode 132b. Details of series connection among solar cells using the type of configuration shown in FIG. 2 may be found in commonly assigned, U.S. Pat. No. 7,276,724 issued Oct. 2, 2007 and fully incorporated herein by reference for all purposes.

In many practical implementations it is common for multiple solar cell modules to be electrically connected in series. In such implementations, the first cell and the last cell in the series of electrically coupled cells in a given module may be respectively connected to an upstream module and a downstream module via electrical wires.

Returning back to FIG. 1, the bottom encapsulant layer 140 may be any of a variety of pottant materials, such as but not limited to Tefzel®, polyvinyl butyral (PVB), ionomer, silicone, thermoplastic polyurethane (TPU), thermoplastic elastomer polyolefin (TPO), tetrafluoroethylene hexafluoropropylene vinylidene (THY), fluorinated ethylene-propylene (FEP), saturated rubber, butyl rubber, thermoplastic elastomer (TPE), flexibilized epoxy, epoxy, amorphous PET, urethane acrylic, acrylic, other fluoroelastomers, other materials of similar qualities, or combinations thereof. The thickness of the bottom encapsulant layer 140 may be in the range of about 400 μm or less.

The backsheet 150 provides protective qualities to the underside of the module 100. Materials made of the backsheet 150 may be a multi-layer structure that provides a vapor barrier, an interface for adhesive used for attachment of the module 100 to a structure, such as roof, and provide dielectric protection and cut resistance. By way of non-limiting example, the backsheet 150 may be a plastic film, PET, EPDM, TPO or a multi-layer structure such as 3M™ Scotchshield™ film 15T or 17T, or Coveme dyMat PYE-3000. As seen in FIG. 1, the backsheet structure 150 may be comprised of dielectric layers 152 and 156 and a vapor barrier layer 154, which may be a metal layer sandwiched between the dielectric layers 152 and 156. The dielectric layer 152 or 156 may be made of any electrically insulating materials such as polyethylene terephthalate, or alumina. Dielectric layer 152 is optional. The thickness of the dielectric layer 152 may be in the range from 0 μm to about 150 μm. The thickness of the dielectric layer 156 may be in the range of about 300 μm to about 1.5 millimeters. One of the dielectric layers 152 or 156 may be optionally removed. Optionally, another protective layer may be applied to the dielectric layer for improvement on the voltage withstand, fill pores/cracks, and/or alter the surface properties of the layer that is dip coated, spray coated, or otherwise thinly deposited on the dielectric layer. Optionally, the protective layer may be comprised of a polymer such as but not limited to fluorocarbon coating, perfluoro-octanoic acid based coating, or neutral polar end group, fluoro-oligomer or fluoropolymer. Optionally, the protective layer may be comprised of a silicon based coating such as but not limited to polydimethyl siloxane with carboxylic acid or neutral polar end group, silicone oligomers, or silicone polymers. In one example, the vapor barrier layer 154 may be made of conductive materials, e.g., a metal layer, such as aluminum foil, that may provide vapor barrier for the module 100. The vapor thickness of the vapor barrier layer 154 may be in a range from 25 μm to about 400 μm. The thickness of the backsheet 150 may be in the range about 25 to about 2000 μm.

One or more conductive tabs 160 may electrically connect the bottom electrode 132 or backside top electrode 134 in the cell array 130 to an electrical wire leading to cells in another modules or an inverter that is part of the module 100. Tabs 160 may be coupled to the electrode by welded connection or soldering. Materials of tabs 160 may be any conductive materials, such as aluminum or copper.

In one embodiment where the module has a conductive substrate, the busbars or electrical routings may be integrated with the vapor barrier layer 154 in the backsheet 150. In particular, the electrically vapor barrier layer 154 may integrate with busbars or other electrical connections to route a circuit via the support layer from one location of the module to another. The vapor barrier layer 154 may similarly be used to electrically connect a solar cell in another module and/or an electrical lead from another module to create an electrical interconnection between modules. Busbars in the vapor barrier layer 154 may be electrically isolated by electrically insulating materials such as PET, EVA and/or combinations thereof. Details of modules having a conductive substrate, such as an aluminum foil, with integration of busbars can be found in commonly assigned, co-pending U.S. patent application Ser. No. ______ (Attorney Docket NSL-0279) filed the same day as the present application and fully incorporated herein by reference for all purposes. In this embodiment, one or more conductive tabs 160 may be electrically connected between the vapor barrier layer 154 and an electrical wire coupled to cells in other modules.

FIG. 3 shows a close-up view of an electrical connection on a module in accordance with the present disclosure. The module 100 in FIG. 3 may include a plurality of cells connected in series. In order to produce more power, the module 100 may be series interconnected with other modules via electrical wires. In one example, the first cell in series in module 100 may be electrically connected to the last cell in series in an upstream module via a wire 170. Specifically, one end of the tab 160 is coupled to the backside top electrode of the first cell in module 100 by soldering or welded connection. The other end of the tab 160 may be coupled to the wire 170 by wrapping the tab around the wire. With one end of the wire 170 connected to the tab 160, the wire 170 may be electrically connected to a cell in an upstream module at the other end, such as the bottom electrode of the last cell in the cell string. Details of connections between modules are described below in associated with FIG. 6. The wire 170 may be made of a conductive material. The wire 70 may have sheathing 172 made of plastic or other insulating material. Alternatively, the wire 170 may be bare metal, or may be insulated wiring with ends that are exposed for soldering or optionally, insulated with a limited area on one surface exposed for soldering. Optionally, the wire 170 may be part of a single core cable, bipolar cable, or a multi-core cable. The wire 170 may be conical in cross section or it may be round, oblong, oval, rectangular, polygonal, the like, or combinations thereof.

The backsheet 150 may be designed as electrically insulated, and thus, it may provide a barrier or a shield for electrical connections by wrapping itself around as shown in FIG. 4. Specifically, the backsheet 150 may be curved inward and wrapped around the connection between the tab 160 and the wire 170. By applying heat, pressure and/or adhesive, the wrapping or fold may include one or more inward curved portions to form a barrier and provide protection for the connection. As such, the backsheet may function as a junction box and thus replacing it to reduce manufacturing cost. Optionally, an additional plastic film may be provided for cut resistance and dielectric strength and also as a “mold” to contain pottant during a manufacturing step. This film may surround a solder or weld joint between the tab 160 and a termination of the wire 170. In addition, a sealant 180 may be applied to provide wet leakage protection for the openings. The sealant 180 may form a circular patch as shown in FIG. 4 or it may be a square patch, oval patch, or other shaped patch. The sealant 180 may be a commercially available sealing material such as Novasil® S49 from Herman Otto GmbH, of Fridolfing, Germany. Optionally, additional strain relief may be provided at the exit point of the wire 170 from the module 100. Such strain relief may be in the form of a gasket, which may be made of a synthetic rubber, such as ethylene propylene diene monomer (M-class) (EPDM) rubber.

FIG. 5 shows one embodiment of solar cell module electrical connections configured in accordance with the present disclosure. The conductive tab 160a may provide electrical connection between, for example, the first cell in the cell string and the wire 170a. The tab 160b may connect the last cell in the string to the wire 170b. The wires 170a and 170b may be respectively coupled to cells in other modules. In addition to electrical wires 170a and 170b, a bypass line 174 may be also provided for transfer of the collected current from one location to another. In one example, the wire 170b may be coupled to the bypass wire 174b and thus the output of the last cell in the string may be routed back via the bypass line 174 and the bypass wire 174a. The bypass line 174, bypass cables 174a and 174b may be conical in cross section or it may be round, oblong, oval, rectangular, polygonal, the like, or combinations thereof. The bypass line 174 may be integrated with the module or alternatively it may be an electrical wire external to the module. In the embodiment where the bypass line 174 is external to the module, it may be free hanging or it may be adhered to the module.

As seen in FIG. 6, the modules 100, 200, 300 and 400 may be series interconnected. This allows the voltages of the modules to be added together for larger scale solar module installations. The modules 100, 200, 300 and 400 each may include a plurality of solar cell that are connected in series and these cell connections are not shown for ease of illustration. It should be understood that numbers of modules than those shown in FIG. 6 may be series interconnected in a repeating fashion similar to that shown in FIG. 6 to link large numbers of modules together. In the prophetic example shown in FIG. 6, the last cell in series in the module 100 is coupled to the first cell in series in the module 200 via wire 170b and 270a so that the collected current from module 100 may be sent to the module 200. In the same manner, the last cell in the module 200 is connected to the first cell in the module 300 via wire 270b and 370a, and the last cell in module 300 is connected to the first cell in the module 400 via wire 370b and 470a. As such, the voltage generated by the four modules may be added up and the last cell in the module 400 may output the collected current. Typically, the output of the last cell in the last module in the series is electrically connected to an inverter together with the input of the first cell in the first module in the series. It may however require long wiring especially when the system involves a large number of modules. Accordingly, a bypass line may be provided to connect the output of the last cell in the last module in the assembly series back to the first module. As shown in FIG. 6, with a jumper for example, the output of the last cell in the module 400 is connected to the bypass wire 474a coupled to the integrated bypass line 474. The collected current is in turn sent back to the first module 100 via multiple bypass wires 474b, 374a, 374b, 274a, 274b, and 174a and bypass lines 374, 274 and 174. The bypass line 174 and the first cell in the module 100 may be coupled to the inputs of an inverter 500 which converts the collected power to a certain desired voltage or alternating current. Optionally, the bypass line 174 and the first cell in module 100 may be connected to other appropriate electrical device, such as a combiner.

While the above is a complete description of the preferred embodiment of the present invention, it is possible to use various alternatives, modifications and equivalents. Any feature described herein, whether preferred or not, may be combined with any other feature described herein, whether preferred or not.

What is claimed is:

1. An apparatus comprising:
one or more solar cells, each of the one or more solar cells including an electrically conductive layer;
an electrically conductive tab electrically connected to the electrically conductive layer of at least one of the one or more solar cells; and
an electrically conductive wire, wherein a portion of the electrically conductive tab is wrapped around the wire and in electrical contact with the wire.

2. The apparatus of claim 1, further comprising an electrically insulating backsheet, wherein the one or more solar cells are attached to the backsheet.

3. The apparatus of claim 1, further comprising an electrically insulating backsheet, wherein the one or more solar cells are attached to the backsheet, wherein a portion of the backsheet is wrapped around and encapsulates the wire and the portion of the tab that is wrapped around the wire.

4. The apparatus of claim 1, wherein the electrically conductive layer is a metal foil layer.

5. The apparatus of claim 4, wherein each cell of the one or more solar cells includes a bottom electrode layer between a device layer and an insulating layer, wherein the insulating layer is between the bottom electrode and a backside top electrode layer.

6. The apparatus of claim 5, wherein the electrically conductive layer is the bottom electrode layer.

7. The apparatus of claim 5, wherein the electrically conductive layer is the backside top electrode layer.

8. The Apparatus of claim 4, wherein the metal foil layer is an aluminum foil layer.

9. The apparatus of claim 4, wherein the wherein the metal foil layer is a vapor barrier layer sandwiched between two insulating layers.

10. A solar module, comprising:
a top layer;
a top encapsulant layer;
a plurality of solar cells sandwiched between the top encapsulant layer and a bottom encapsulant layer;
wherein each solar cell in the plurality of solar cells includes an electrically conductive layer, an electrically conductive tab electrically connected to the electrically conductive layer of at least one of the one or more solar cells; and
an electrically conductive wire, wherein a portion of the electrically conductive tab is wrapped around the wire and in electrical contact with the wire.

11. The solar module of claim 10, wherein the electrically conductive layer is a metal foil layer.

12. The solar module of claim 11, wherein each cell of the one or more solar cells includes a bottom electrode layer between a device layer and an insulating layer, wherein the insulating layer is between the bottom electrode and a backside top electrode layer.

13. The solar module of claim 12, wherein the electrically conductive layer is the bottom electrode layer.

14. The solar module of claim 12, The apparatus of claim 1, wherein the electrically conductive layer is the backside top electrode layer.

15. The solar module of claim 11, wherein the metal foil layer is a vapor barrier layer sandwiched between two insulating layers.

16. The solar module of claim 10, wherein the solar cells in the plurality of solar cells are electrically connected in series.

17. The solar module of claim 5, wherein the electrically conductive tab electrically connected to the electrically conductive layer of a first or last of the solar cells electrically connected in series.

18. The solar module of claim 10, further comprising a bypass wire integrated into the module.

19. The solar module of claim 10, further comprising an electrically insulating backsheet, wherein the bottom encapsulant layer is attached to the backsheet.

20. The solar module of claim 19, wherein a portion of the backsheet is wrapped around and encapsulates the wire and the portion of the tab that is wrapped around the wire.
